(19) United States
(12) Patent Application Publication
(10) Pub. No.: US 2024/0303405 A1
(43) Pub. Date: Sep. 12, 2024

(54) DYNAMIC REFINEMENT OF HARDWARE ASSERTION CHECKERS

(71) Applicant: University of Florida Research Foundation, Incorporated, Gainesville, FL (US)

(72) Inventors: Prabhat Kumar Mishra, Gainesville, FL (US); Hasini Dilanka Witharana, Gainesville, FL (US); Sahan Sanjaya Nelundeniyalage, Gainesville, FL (US)

(21) Appl. No.: 18/595,698

(22) Filed: Mar. 5, 2024

Related U.S. Application Data
(60) Provisional application No. 63/489,020, filed on Mar. 8, 2023.

(51) Int. Cl. G06F 30/3323; G06F 30/398

(52) U.S. Cl. CPC G06F 30/3323; G06F 30/398

(57) ABSTRACT

Embodiments provide for dynamically refining hardware assertion checkers of an integrated circuit (IC) design. An example method includes receiving a plurality of hardware assertion checkers and receiving one or more design constraints. The example method further includes, based at least in part on applying a cost prediction model to the plurality of hardware assertion checkers, generating a predicted overhead cost associated with the plurality of hardware assertion checkers. The example method further includes, based at least in part on the predicted overhead cost and the one or more design constraints, selecting an optimal hardware assertion checker set. The example method further includes synthesizing the optimal hardware assertion checker set.

### CROSS-REFERENCE TO RELATED APPLICATIONS

The present application claims priority to U.S. Provisional Application Ser. No. 63/489,020, titled “DYNAMIC REFINEMENT OF HARDWARE ASSERTION CHECKERS,” filed Mar. 8, 2023, the entire contents of which are incorporated herein by reference.

### STATEMENT REGARDING GOVERNMENT SUPPORT

This invention was made with government support under 1908131 awarded by National Science Foundation. The government has certain rights in the invention.

### BACKGROUND

Post-silicon validation is a vital step in System-on-Chip (SoC) design cycle. A major challenge in post-silicon validation is the limited observability of internal signal states using trace buffers. Hardware assertions are promising to improve the observability during post-silicon debug. Unfortunately, synthesis of thousands (or millions) of pre-silicon assertions as hardware checkers (coverage monitors) is not feasible due to hardware overhead constraints. Prior efforts considered synthesis of a small set of checkers based on design constraints. However, these design constraints can change dynamically during the device lifetime due to changes in use-case scenarios as well as input variations.

Through applied effort, ingenuity, and innovation, many of these identified deficiencies and problems have been solved by developing solutions that are structured in accordance with embodiments of the present disclosure, many examples of which are described in detail herein.

### BRIEF SUMMARY

Embodiments provide for dynamically refining hardware assertion checkers of an integrated circuit (IC) design. An example method includes receiving a plurality of hardware assertion checkers and receiving one or more design constraints. The example method further includes, based at least in part on applying a cost prediction model to the plurality of hardware assertion checkers, generating a predicted overhead cost associated with the plurality of hardware assertion checkers. The example method further includes, based at least in part on the predicted overhead cost and the one or more design constraints, selecting an optimal hardware assertion checker set. The example method further includes, synthesizing the optimal hardware assertion checker set.

The above summary is provided merely for purposes of summarizing some example embodiments to provide a basic understanding of some aspects of the present disclosure. Accordingly, it will be appreciated that the above-described embodiments are merely examples and should not be construed to narrow the scope or the spirit of the present disclosure in any way. It will be appreciated that the scope of the present disclosure encompasses many potential embodiments in addition to those here summarized, some of which will be further described below. Other features, aspects, and advantages of the subject matter will become apparent from the description, the drawings, and the claims.

### BRIEF DESCRIPTION OF THE DRAWINGS

Having thus described certain example embodiments of the present disclosure in general terms above, non-limiting and non-exhaustive embodiments of the subject disclosure will now be described with reference to the accompanying drawings which are not necessarily drawn to scale. The components illustrated in the accompanying drawings may or may not be present in certain embodiments described herein. Some embodiments may include fewer (or more) components than those shown in the drawings. Some embodiments may include the components arranged in a different way:

FIGS. 1A and 1B depict an example assertion-based validation framework, in accordance with embodiments of the present disclosure.

FIG. 2A depicts an example clustering-based assertion selection framework, in accordance with embodiments of the present disclosure.

FIG. 2B depicts an example dynamic refinement framework, in accordance with embodiments of the present disclosure.

FIG. 3 depicts an example clustering-based assertion selection algorithm, in accordance with embodiments of the present disclosure.

FIG. 4 depicts an example dynamic refinement of checkers algorithm, in accordance with embodiments of the present disclosure.

FIG. 5 depicts example fault coverage results, in accordance with embodiments of the present disclosure.

FIG. 6 depicts example power consumption results, in accordance with embodiments of the present disclosure.

FIGS. 7A and 7B depict example model accuracy, in accordance with embodiments of the present disclosure.

FIG. 8 depicts example dynamic refinement of hardware checkers for benchmarks with different constraints, in accordance with embodiments of the present disclosure.

### DETAILED DESCRIPTION

Various embodiments of the present disclosure are described more fully hereinafter with reference to the accompanying drawings, in which some, but not all embodiments of the present disclosure are shown. Indeed, the present disclosure may be embodied in many different forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Terms such as “computing,” “determining,” “generating,” and/or similar words are used herein interchangeably to refer to the creation, modification, or identification of data. Further, “based on,” “based at least in part on,” “based at least on,” “based upon,” and/or similar words are used herein interchangeably in an open-ended manner such that they do not necessarily indicate being based only on or based solely on the referenced element or elements unless so indicated. Like numbers refer to like elements throughout. Moreover, while certain embodiments of the present disclosure are described with reference to predictive data analysis, one of ordinary skill in the art will recognize that the disclosed concepts can be used to perform other types of data analysis.

### I. OVERVIEW, TECHNICAL IMPROVEMENTS, AND TECHNICAL ADVANTAGES

Embodiments herein provide for dynamic refinement of hardware checkers based on changing design constraints. Specifically, a cost-based assertion selection framework is described that utilizes non-linear optimization as well as machine learning. Experimental results demonstrate that embodiments herein can accurately predict area (less than 5% error) and power consumption (less than 3% error) of hardware checkers at runtime. This accurate prediction enables close-to-optimal dynamic refinement of checkers based on design constraints.

Post-silicon validation is widely used to detect and fix bugs in integrated circuits after manufacturing. Due to the increasing design complexity, it is infeasible to detect all functional as well as electrical bugs during pre-silicon validation. Therefore, post-silicon validation is an essential step in SoC design methodology. One of the biggest challenges in post-silicon validation is the lack of observability of internal states. Typically, a small trace buffer is used to trace few hundred signals (out of millions of signals) during runtime. A prominent avenue to improve post-silicon observability is to use hardware checkers (assertions). Around 75% of ASIC design and 50% of FPGA design projects use assertion-based validation. However, assertions also introduce hardware overhead. Therefore, it is not practical to synthesize thousands or millions of pre-silicon assertions to post-silicon checkers.

Efforts have been made to select the most beneficial set of assertions as hardware checkers based on area, power, and performance constraints. The selected assertions may not be beneficial since the design constraints can change dynamically during the device lifetime due to changes in use-case scenarios as well as input variations. For example, mobile phone usage pattern can drastically change between two users. Even for the same user, the usage of the phone varies during the different time periods of a day. In other words, different use-case scenarios and input variations can lead to dynamic changes in power and performance. Moreover, the dynamic changes in design constraints can limit the resources available for the hardware checkers. For example, the checkers can be disabled when the phone battery is low, which compromises the run-time checking capability. If the reconfigurability is available, it would be beneficial to dynamically refine the checkers to satisfy both dynamically changing circumstances and runtime checking objectives.

Embodiments herein overcome the aforementioned drawbacks and more by incorporating a dynamic refinement framework into assertion-based validation. During pre-silicon validation, assertions for a given design are generated. Due to design overhead constraints, assertion selection can be used to identify the most profitable assertions. The selected assertions are synthesized as hardware checkers. The hardware checkers are used for a dynamic refinement framework. A regression model is trained to predict the cost (power and area) of synthesizing a set of checkers. When the design constraints change dynamically, the subset selection uses the regression model to select the optimal subset of checkers that satisfies the design constraints at that time. The selected checkers are synthesized in reconfigurable hardware.

Embodiments herein provide technical contributions including: formulation of the dynamic refinement problem as a cost-based non-linear optimization problem; using regression based machine learning techniques to perform cost prediction for hardware checkers; solving the non-linear optimization problem using gradient decent with simulated annealing; and demonstrating close-to-optimal dynamic refinement of hardware checkers.

### II. AUTOMATED ASSERTION GENERATION TECHNIQUES AND POST-SILICON ASSERTION SYNTHESIS

### A. Assertion Generation Using Goldmine

Goldmine is an automated assertion generation framework that utilizes static analysis and data mining techniques to automatically generate assertions. First, the design under test is simulated using random inputs to generate behavioral data. Next, design constraints such as cone-of-influence and topographical variable ordering are extracted through static analysis. The core assertion miner employs decision tree-based supervised learning to analyze the simulation traces and design constraints to produce candidate assertions. These candidate assertions are verified through a formal verification engine that supports SMV. Finally, the verified assertions are ranked using support and confidence metrics.

### B. Automatic Template-Based Assertion Miner (A-TEAM)

A-Team is a template-based approach for assertion mining. This method addresses issues such as limited flexibility caused by pre-defined templates and the presence of redundant assertions. First, the Apriori algorithm is used to mine atomic propositions with high frequencies. Next, LTL assertions are mined by combining the atomic propositions obtained in the previous step. These combinations adhere to the user-provided templates. Finally, the mined assertions undergo evaluation against fault coverage, and assertions that do not improve fault coverage are discarded. A minimization process is applied to eliminate redundant assertions.

### C. Hint-Based Assertion Miner (HARM)

HARM is a hint-based automated assertion generation framework. HARM generates LTL assertions based on a collection of user-defined hints and simulation traces of the design under verification. This tool does not need the actual source code of the design since the assertion generation relies on the traces. The user-defined hints consist of LTL templates, propositions, and ranking metrics, which are utilized by the assertion miner to reduce the search space and enhance the quality of the generated assertions.

### D. Ranking of Pre-Silicon Assertions

Goldmine has implemented importance/complexity-based ranking (IRank) and statement coverage-based ranking (SRank) methods. SRank is the ratio between the number of statements of a Verilog program covered by an assertion and the total number of statements in the design, including blocking, non-blocking, and conditional. IRank is the ratio between the assertion importance with respect to a target variable and the assertion complexity. Goldmine ranks assertions with respect to a target variable. Therefore, it is challenging to compare two or more sets of assertions with different target variables to select the best minimized set of assertions. Moreover, Goldmine only supports a limited number of assertion templates and does not support variables with non-Boolean data types.

A-TEAM has the ability to select the minimum number of assertions to maximize fault coverage. The primary strategy behind this minimization is to avoid assertions whose fault coverage can be claimed by others. One major drawback of this method is that it requires simulation of the design with testable faults to find the fault coverage. Also, A-TEAM does not provide individually ranked assertions. Therefore, it is hard to find a small set of assertions that can maximize the fault coverage from the resultant assertions.

HARM supports a configurable and general context-based approach to rank the generated assertions. Users can define ranking and filtering metrics using different built-in assertion features. HARM allows multiple ranking metrics in a single ranking process, enabling the selection of assertions that perform well for most of the ranking metrics. A new metric has been introduced to rank assertions based on the quality of the assertions, which indicates the fault coverage. The main challenge in this minimization method is the long simulation time because it requires injecting some faults into the design and simulation to find the fault coverage of each assertion. Embodiments herein can minimize the number of assertions while maintaining considerable fault coverage without requiring simulation.

### E. Refinement of Post-Silicon Checkers

Pre-silicon assertions can be utilized during post-silicon debug by synthesizing them as hardware checkers. A major challenge in assertion selection is to determine which assertions should be added to the design as hardware checkers. The number of hardware checkers can be reduced by utilizing the existing debug infrastructure (trace buffer). Another promising alternative for cost-effective hardware checkers is the dynamic synthesis of checkers using FPGA. The hardware checkers are included in a re-configurable embedded block (FPGA) in a time-multiplexed manner. This approach enables the addition of a large number of checkers with a low area overhead. Formulas can be converted in LTL over finite traces into automata implementations on FPGAs for high-performance runtime monitoring. All of these approaches rely on static optimization results that may not be optimal under changing circumstances during runtime.

### III. EXAMPLE EMBODIMENTS

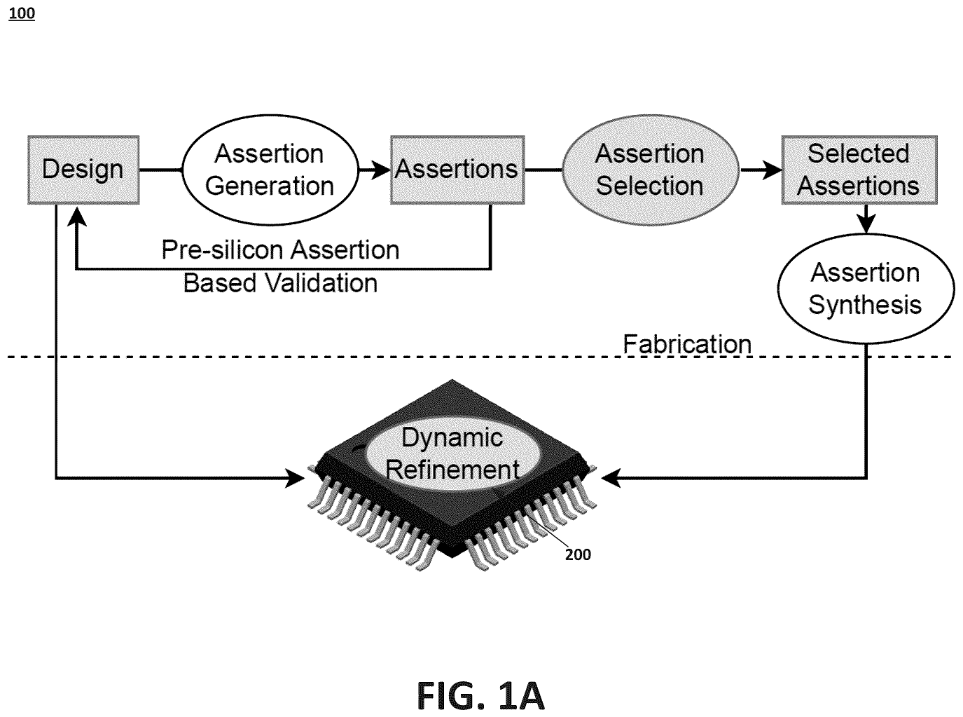

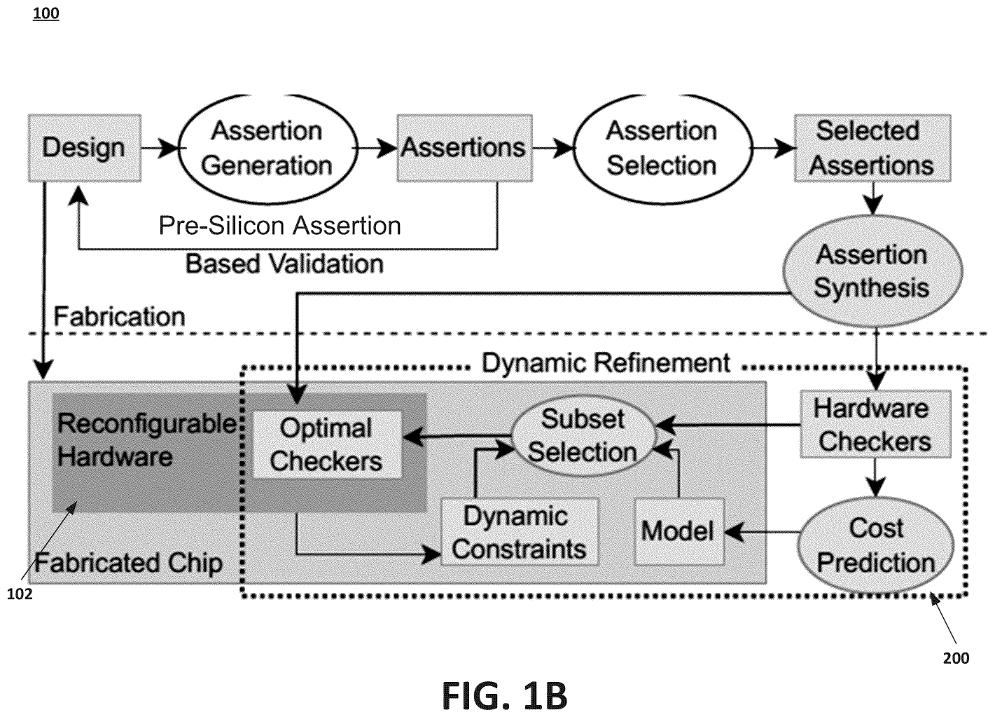

FIGS. 1A and 1B depict an example assertion-based post-silicon validation framework 100, in accordance with embodiments of the present disclosure. The example assertion-based validation framework 100 incorporates an example dynamic refinement framework 200, which uses hardware checkers and employs cost prediction for selecting an optimal set of hardware checkers that satisfies design constraints. The selected hardware checkers are synthesized in reconfigurable hardware 102.

### A. Example Terminology

Definition 1: An assertion can be viewed as a function, assert(expression), which fails when the expression evaluates to false. Examples of assertions include assert(req), assert(req→ack), etc. Linear temporal logic assertion in the form of assert(antecedent→consequent) is evaluated herein, since the existing assertion generators also produce the same type of assertions.

Definition 2: Non-vacuous failing state of an assertion is a Boolean state where antecedent becomes true and consequent becomes false. Moreover, this state represents an unexpected or invalid behavior in the given design. If an assertion has a large number of non-vacuous failing states, it is likely to capture more unexpected or invalid behaviors. Therefore, such an assertion is expected to provide higher fault coverage.

Definition 3: Both antecedent and consequent are some combinations of propositions. A proposition is a statement that is either true or false, but not both. Propositions can be combined using Boolean operators (such as AND, OR, NOT) and logical operators (such as implication and equivalence). For example, consider propositions P1: (illegal_instr==1), P2: (instr <428), P3: (instr >228), and P4: (!is_compressed). They can be combined to form new propositions, such as “P1&P2”, “P3→P4”, “P1 ##5 P4”, etc.

Definition 4: Any proposition of the form Pₓ ##N P_{y} can be mapped to Pₓ[−N] && P_{y}, where Pₓ[−N] indicates that the value of Pₓ N clock cycles is checked earlier relative to P_{y}. Note that now Pₓ and Pₓ[−N] are considered as two different propositions. For example, the combined proposition (P₁ ##2 P₁ ##1 P₁) is mapped into (P₁[−3] && P₁[−1] && P₁). Here, P₁[−3], P₁[−1], and P₁ are considered as three different propositions.

Definition 5: A set of assertions can be defined as A={a₁, . . . , aᵢ, . . . , aₒ}. Here o=n(A), where n(A) is the cardinality of the set A, and aᵢ is a linear temporal logic assertion in the form of antecedent→consequent. Antecedents and consequents that only consist of propositions combined with the AND operator and the ##N are considered herein. By applying Definition 4 to the assertions in set A, a set of assertions is obtained, where the antecedent and consequent are composed solely of propositions combined with the AND operator.

Definition 6: m mutually exclusive subsets (clusters) A₁, A₂, . . . , Aₕ, . . . , Aₘ can be constructed based on the similarity of assertions in terms of covered non-vacuous failing states, where 1≤m≤n(A), and n(A₁)+n(A₂)+ . . . +n(Aₘ)=n(A). In other words, every element in a given subset exhibits full or partial redundancy in terms of covered non-vacuous failing states with other elements in the same subset.

Definition 7: Consider a subset (cluster) Aₕ with l similar assertions, {a₁, a₂, . . . , aₗ}. a_{d} is selected as the dominating assertion in Aₕ if the set of covered non-vacuous failing states by assertions a₁, a₂, . . . , aₗ excluding a_{d}, is a subset of covered non-vacuous failing states by a_{d}.

Definition 8: The set U represents the set of unique propositions that are used in assertions of set A. For example, if the set A={P1&P2→P3, P2→P3&P4,}, then U={P1, P2, P3, P4}.

Definition 9: Let us define Uₛ^{at} and Uₛ^{ct} as the set of antecedent and consequent propositions, respectively, in the assertion aₛ. Similarly, P_{s,i}^{at} and P_{s,i}^{ct} represent the i-th proposition in the set Uₛ^{at} and Uₛ^{ct}, respectively. Both Uₛ^{at} and Uₛ^{ct} are subsets of U. For example, if an assertion a₉=(P1&P2&P3)→(P4&P5), U₉^{at}={P1, P2, P3} and U₉^{ct}={P4, P5}.

Definition 10: The set Bₛ^{at} is defined as the set of Boolean states, where the antecedent of the assertion as becomes true. Similarly, Bₛ^{ct} represents the set of Boolean states, where the consequent of the assertion as becomes false. Elements of sets Bat s and Bct s are represented as binary values with n(U) number of bits, where each bit represents the Boolean value of a proposition in U. For example, if the assertion a10=P1→P2, and U=(P1, P2, P3), then B₁₀^{at}={100, 101, 110, 111}, and B₁₀^{ct}={000, 001, 100, 101}.

Definition 11: The non-vacuous failing states of the assertion as can be expressed as the set Bₛ^{at}∩Bₛ^{ct}. For example, the set of non-vacuous failing states of the assertion a10, as defined in Definition 10, is the set B₁₀^{at}∩Bₛ^{ct}={100, 101}.

### B. Assertion Selection

The objective of assertion selection is to select the minimum number of assertions while maintaining considerable fault coverage. The goal is to select m assertions from the set A that has o assertions, where m<<o. There are

$$\frac{o !}{m ( o - m ) !}$$

possible combinations to select the m assertions. This number of combinations increases significantly as the size of the initial assertion set A grows. If m assertions are selected randomly, there is no guarantee that the selected assertions will meet the objective. Therefore, it is critical to rank the assertions based on their ability to cover faulty behaviors and select the top-ranked assertions. As highlighted herein, there are major challenges in state-of-the-art assertion ranking schemes. A framework is discussed herein to first construct m subsets (clusters), where each cluster includes similar assertions as outlined in Definition 6. The final minimized set of assertions consists of the collection of all the dominating assertions selected from each subset as outlined in Definition 7. Specifically, the following needs to be solved:

$$\begin{matrix}{constructSubset}_{1 \leq i \leq m} ( {A}_{i} ) \\ {selectDominator}_{1 \leq i \leq m} ( {A}_{i} )\end{matrix}$$

Two major challenges exist in solving the assertion selection problem: (i) how to cluster a set of similar assertions without simulation, and (ii) how to find the dominating assertion in each cluster. Solutions are discussed herein. The selected assertions are then synthesized as hardware checkers. Note that the design constraints may change dynamically during the device's lifetime, and the synthesized assertions should be able to adapt to these changes as outlined herein.

### C. Dynamic Refinement

Cost-based optimization is a powerful technique to address the problem of selecting a set of choices. It consists of associating costs with various choices and then finding the subset of choices with the smallest cost. The selection of hardware checkers is defined herein as a cost-based optimization problem. The cost-based optimization problem can be defined as:

$$\begin{matrix}{minimize}_{S} ( ( S ) ) \\ ( S ) \leq powerBudget , ( S ) \leq areaBudget\end{matrix}$$

where S is a subset of checkers and PW and AR encode power and area constraints, respectively. F encodes the cost of the design and F(S) can depend on any of the power or area related costs together with any other considerations. In general, F(S) is non-linear (e.g., not a simple summation of cost for checker) and may depend on the subset of checkers that are implemented.

There are challenges in solving this optimization problem. A first challenge computing the functions F, PW and AR given that there are 2^{m} possible inputs, where m is the number of checkers in the set S. Computing the functions is challenging because estimating power or area for a given design requires expensive synthesis. Performing such an estimation for 2^{m} designs is infeasible. Embodiments herein leverage machine learning techniques to treat the estimation problem as a regression problem. Instead of generating all possible designs, a small subset is generated and estimates for area and power are learned.

A second challenge is solving the optimization problem (e.g., identifying the set S that minimizes the cost while satisfying design constraints). Solving the problem is challenging due to the size of the search space and the fact that the problem is non-linear. The non-linearity translates into a potentially large number of local minimums. To overcome these challenges, embodiments herein utilize non-linear optimization techniques.

Embodiments herein can be implemented inside a System-on-Chip (SoC) that is the brain of a wide variety of embedded systems, including tablets, smartphones, cars as well as airplanes. Embodiments herein include one or more machine learning (ML) models and hardware assertions (checkers). The ML model(s) can be implemented in hardware using one or more Application Specific Integrated Circuits (ASIC), Tensor Processing Units (TPU) or Field Programmable Gate Arrays (FPGA). The ML model(s) can also be executed in software using Central Processing Unit (CPU) or Graphics Processing Unit (GPU) architectures. The hardware assertions (checkers) can be implemented in a programmable fabric, such as an FPGA.

Embodiments herein can be utilized in various scenarios, including (i) post-silicon debugging of integrated circuits or (ii) on-chip debugging after deployment in the field. In the first scenario, the verification engineers are interested in verifying the integrated circuit after fabrication. In the second scenario, the field engineers are interested in debugging the final product (e.g., a smartphone) that contains this SoC with dynamic refinement capability.

Embodiments herein involve both offline running time and online running time. Offline running time includes the time for training the machine learning model for the cost prediction stage. Online running time consists of the time to choose the optimal checker set based on different constraints. The offline running time may be in the range of hours and the online running time may be in the range of seconds or shorter. Since training is conducted separately before fabrication, the training time does not affect the run time of the fabricated chip. The overhead of including this technology in the chip consists of the area overhead of storing the ML model(s) and the optimization program. The ML model(s) and the optimization program can be stored in the memory or in the Electrically Erasable Programmable Read-only Memory (EEPROM) of the chip. The memory requirement for the ML model(s) may be around 5 KB and the memory requirement for storing the optimization program/application may be around 10 KB.

It will be appreciated that overhead cost, as referred to herein, may include power, area, thermal, temperature, accuracy, functional coverage, security, vulnerability coverage, debuggability, and other types of overhead, or combinations thereof.

### D. Clustering-Based Assertion Selection

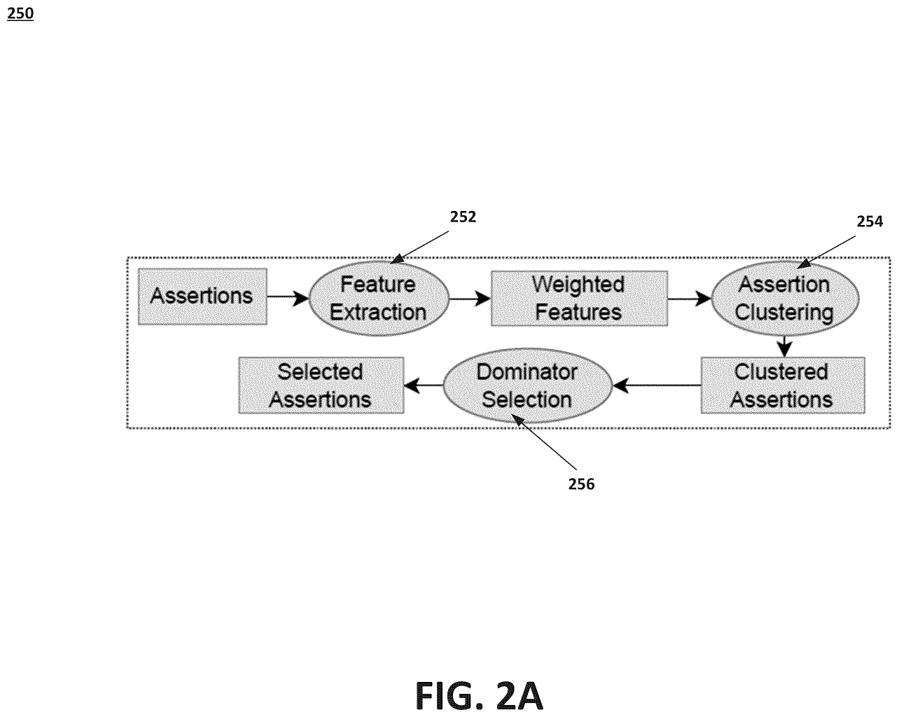

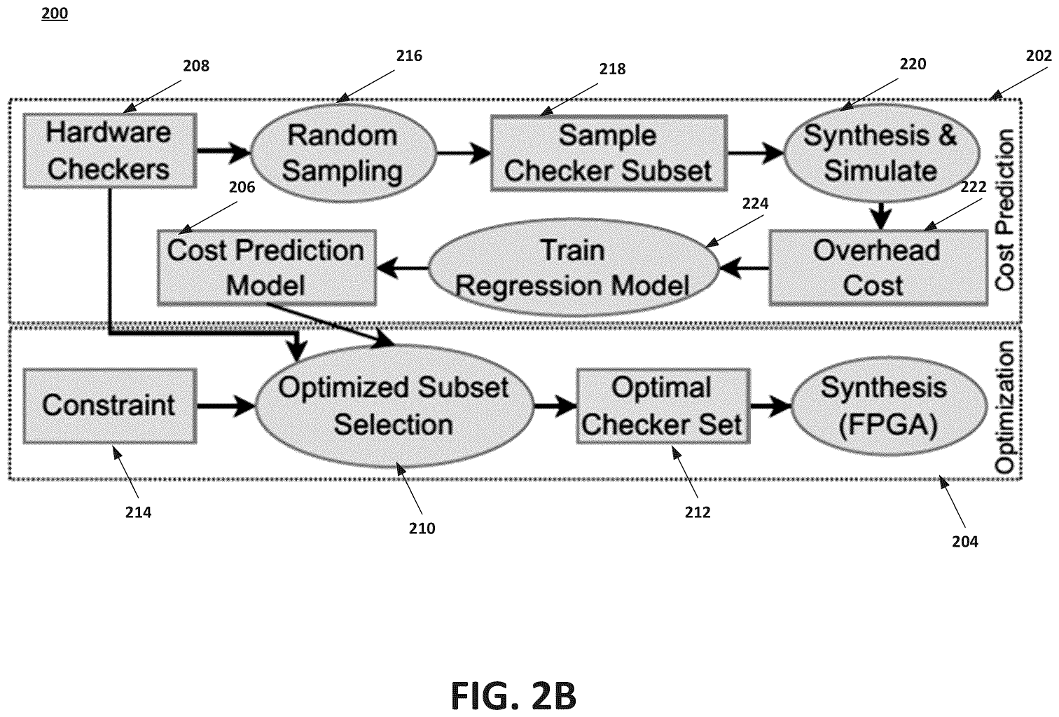

FIG. 2A depicts an example clustering-based assertion selection framework 250, in accordance with embodiments herein. It includes feature extraction 252, assertion clustering 254, and selection 256 of dominating assertion from each cluster. The feature extraction 252 identifies beneficial features from assertions. The assertion clustering 254 clusters similar assertions based on the similarity of the features. Dominator selection 256 selects one dominating assertion from each cluster to get the final minimized set of assertions.

### 1. Feature Extraction 252

Assume that aⱼ, aₖ∈A.
Lemma IV.1. If P₁&P₂ is true, then P₁ is true, where P₁, P₂∈U.
Theorem IV.2. Uⱼ^{at}⊆Uₖ^{at}→Bₖ^{at}⊆Bⱼ^{at}
Proof Assume that Uⱼ^{at} is a subset of Uₖ^{at}, then n(Uⱼ^{at})≤n(Uₖ^{at}), and ∀P_{j,r}^{at}∈Uⱼ^{at}, ∃! P_{k,t}^{at}∈Uₖ^{at} such that P_{j,r}^{at}=P_{k,t}^{at}. Therefore, we can express the antecedent of aₖ in the form of X&Y, where X is the antecedent of aⱼ and Y represents the combination of all propositions in (Uₖ^{at}−Uⱼ^{at}) using the AND operator. Using the Lemma IV.1 (X&Y→X), we can conclude that whenever the antecedent of aₖ becomes true, the antecedent of aⱼ becomes true. Therefore, Bₖ^{at} is a subset of Bⱼ^{at}. □
Lemma IV.3. If P₁ is false, then P₁&P₂ is false, where P₁, P₂∈U.
Theorem IV.4. Uₖ^{ct}⊆Uⱼ^{ct}→+Bⱼ^{ct}
Proof. Assume that Uₖ^{ct} is a subset of Uⱼ^{ct}, then n(Uₖ^{ct})≤n(Uⱼ^{ct}), and ∀P_{k,g}^{ct}∈Uₖ^{ct}, ∃! P_{j,h}^{ct}∈Uⱼ^{ct} such that P_{k,g}^{ct}=P_{j,h}^{ct}. Therefore, we can express the consequent of aⱼ in the form of Q&R, where Q is the consequent of aₖ and R represents the combination of all propositions in (Uⱼ^{ct}−Uₖ^{ct}) using the AND operator. Using the Lemma IV.3 (¬Q→¬(Q&R)), we can conclude that whenever the consequent of aₖ becomes false, the consequent of aⱼ becomes false. Therefore. Bₖ^{ct} is a subset of Bⱼ^{ct}. □
Theorem IV.5. Uⱼ^{at}⊆Uₖ^{at} and Uₖ^{ct}⊆Uⱼ^{ct}→(Bₖ^{ct} ⊆Bₖ^{ct})⊆(Bⱼ^{at}∩Bⱼ^{ct})
Proof. If x∈(Bₖ^{at}∩Bₖ^{ct}), then x∈Bₖ^{at} and x∈Bₖ^{ct}. According to Theorem IV.2. Bₖ^{at}⊆Bⱼ^{at}, and therefore x∈Bₖ^{at}. According to Theorem IV.4, Bₖ^{ct}⊆Bⱼ^{ct}, and therefore x∈Bⱼ^{ct}. In other words, x∈(Bⱼ^{at}∩Bⱼ^{ct}). Therefore. ∀x∈(Bₖ^{at}∩Bₖ^{ct}), x∈(Bⱼ^{at}∩Bⱼ^{ct}). Therefore. (Bₖ^{at}∩Bₖ^{ct}) is a subset of (Bⱼ^{at} ∩Bⱼ^{ct}).
Lemma IV.6. If (C⊆D) and (C⊆E), then (C∩D∩E≠∅), where C, D, and E are nonempty sets.

According to Theorem IV.5, Definition 7, and Definition 11, the assertion with the fewest number of antecedent propositions and the largest number of consequent propositions is the dominating assertion (a_{d}) among two assertions that have a relationship like in Theorem IV.5. This is because one assertion has full redundancy compared to covered non-vacuous failing states with the other. When finding a dominating assertion from a set of assertions, if any two assertions in the set are compared, they both should have properties as in Theorem IV.5. Then that set has a similarity property among elements as defined in Definition 6. Hence, according to Lemma IV.6, there should be at least one common proposition in the antecedent and at least one common proposition in the consequent in the set. Therefore, the assertion with the fewest number of antecedent propositions and the largest number of consequent propositions is the dominating assertion in a set of linear temporal logic assertions in the form of antecedent→consequent. This holds true when the assertions in the set have at least one common proposition in the antecedent and at least one common proposition in the consequent.

TABLE I
Truth Table with four propositions

| State | P₁ | P₂ | P₃ | P₄ |
|---|---|---|---|---|
| s0 | 0 | 0 | 0 | 0 |
| s1 | 0 | 0 | 0 | 1 |
| s2 | 0 | 0 | 1 | 0 |
| s3 | 0 | 0 | 1 | 1 |
| s4 | 0 | 1 | 0 | 0 |
| s5 | 0 | 1 | 0 | 1 |
| s6 | 0 | 1 | 1 | 0 |
| s7 | 0 | 1 | 1 | 1 |
| s8 | 1 | 0 | 0 | 0 |
| s9 | 1 | 0 | 0 | 1 |
| s10 | 1 | 0 | 1 | 0 |
| s11 | 1 | 0 | 1 | 1 |
| s12 | 1 | 1 | 0 | 0 |
| s13 | 1 | 1 | 0 | 1 |
| s14 | 1 | 1 | 1 | 0 |
| s15 | 1 | 1 | 1 | 1 |

TABLE II
Sample assertions and non-vacuous failing states

| | | | # Non- |
|---|---|---|---|
| | | | vacuous |
| | | | failing |
| aᵢ | Assertion | Non-vacuous failing states | states |
| a₁ | P₁ → P₂&P₃&P₄ | s8, s9, s10, s11, s12, s13, s14 | 7 |
| a₂ | P₁ → P₂&P₃ | s8, s9, s10, s11, s12, s13 | 6 |
| a₃ | P₁ → P₂&P₄ | s8, s9, s10, s11, s12, s14 | 6 |
| a₄ | P₁ → P₂ | s8, s9, s10, s11 | 4 |
| a₅ | P₁&P₃ → P₂&P₄ | s10, s11, s14 | 3 |
| a₆ | P₁&P₃ → P₂ | s10, s11 | 2 |
| a₇ | P₁&P₄ → P₂ | s9, s11 | 2 |
| a₈ | P₁&P₃&P₄ → P₂ | s11 | 1 |

For example, consider a set of assertions that contains four unique propositions: P₁, P₂, P₃, and P₄. Table I shows the truth table for all possible assertions using these four propositions. Note that this simple example is used to illustrate the theories. Nevertheless, these theories are valid for any common scenarios. Table II shows eight possible linear temporal logic assertions. By using Table I, it is possible to find all the non-vacuous failing states for every assertion listed in Table II. The third column of Table II represents respective non-vacuous failing states. It highlights the fact that the assertion with the fewest antecedent propositions and the most consequent propositions has more non-vacuous failing states, and it covers the non-vacuous failing states of all other listed assertions. According to Table II, if an assertion like a₁ can be found, it can cover all non-vacuous failing states that are covered by other assertions in the same group (Theorem IV.5).

If an assertion like at does not exist in the assertion set, then the next best options are a₂ or a₃. However, choosing assertions other than a₁ may result in uncovered non-vacuous failing states based on the set of assertions. For example, if a₂ is selected and a₃ or as exists in the assertions set, the uncovered non-vacuous failing state is state s14. Suppose expand the a₂, a₃ and a₅ assertions are expanded (using the Boolean tautology: p=(p&q)|(p&¬q), where p and q are Boolean propositions) as follows:

$${α}_{2} : ( {P}_{1} \& {P}_{3} ) \vert ( {P}_{1} \& ¬ {P}_{3} ) \to ( {P}_{2} \& {P}_{3} \& {P}_{4} ) \vert ( {P}_{2} \& {P}_{3} \& ¬ {P}_{4} ) \\ {α}_{3} : ( {P}_{1} \& {P}_{3} ) \vert ( {P}_{1} \& ¬ {P}_{3} ) \to ( {P}_{2} \& {P}_{3} \& {P}_{4} ) \vert ( {P}_{2} \& {P}_{4} \& ¬ {P}_{3} ) \\ {α}_{5} : ( {P}_{1} \& {P}_{3} ) \to ( {P}_{2} \& {P}_{3} \& {P}_{4} ) \vert ( {P}_{2} \& {P}_{4} \& ¬ {P}_{3} )$$

Some common propositions can be found in the antecedent and the consequent parts of expanded a₂, a₃ and a₅ assertions. If the antecedent of a₅ becomes true, the antecedent of a₃ also becomes true because they have a common antecedent proposition, in this case, (P1&P3). If the consequent of a₅ becomes false, the consequent of a3 also becomes false because they have common consequent propositions, in this case, (P2&P3&P4)|(P2&P4&¬P3). Thus, a₅ can be removed from the set while keeping a₃.

The same analysis can be applied to assertions a₂ and a₃. Between a₂ and a₃, if the antecedent of one of them becomes true, the antecedent of the other also becomes true. However, in the consequent part, even though both assertions have a common proposition, it is not guaranteed that every time the consequent of a₂ becomes false, the consequent of a₃ also becomes false. The reason for this is that both assertions have unique propositions in the consequent that are not common for both, in this case, (P2&P3&¬P4) in a₂ and (P2&P4&¬P3) in a₃. Thus, some non-vacuous failing states are not common for both assertions. If either a₂ or aw is chosen, there are some uncovered non-vacuous failing states. Discussion of embodiments herein shows that the reduction in the covered non-vacuous failing states only has a minor impact. Therefore, an efficient way for the minimization is to create clusters where each assertion in the cluster comprises at least one common antecedent proposition and at least one common consequent proposition.

To implement the above clustering method, the feasible features are the unique propositions in the antecedent and consequent, which are the basis propositions of the given set of assertions. While this feature extraction is promising, it is not practical to always find clusters that satisfy both of the following conditions: (1) every assertion in the cluster must have at least one common proposition in the antecedent, and (2) every assertion in the cluster must have at least one common proposition in the consequent. It is possible to eliminate or modify the above two conditions while giving more flexibility to the clustering algorithm. This enables exploration os either common antecedent-based clustering or common consequent-based clustering.

The applicability of antecedent-based versus consequent-based clustering using five benchmarks is evaluated. Table III shows that for every benchmark, there are only a few unique propositions in the consequent compared to the antecedent. Therefore, there are more assertions with the same consequent proposition than assertions with the same antecedent proposition. Thus, clusters based on common consequent propositions contain more similar assertions in every cluster than clusters based on common antecedent propositions. This allows for minimizing the initial assertion set by a considerable amount while maintaining significant fault coverage. Therefore, embodiments herein utilize consequent-based clustering, where every assertion in the cluster has at least one common proposition in the consequent.

To implement consequent-based clustering, a higher weight (e=2) is used for propositions in consequent than in the antecedent (e=1) as feature values. This weighing method reflects the importance of the propositions in the consequent when considering them as feature values for clustering. Lines 2-18 of Algorithm 1 show the major steps of the abovementioned feature extraction, which produces extracted quantified feature array (E) as the output. The algorithm begins by constructing two sets: AN and CO. The set AN contains all the unique propositions found in the antecedents of each assertion in the set A. Similarly, the set CO contains all the unique propositions found in the consequent of each assertion in the set A. These two sets are used to quantify the features of each assertion to produce the set of extracted features (E).

TABLE III
Unique propositions in antecedent and consequent using
five benchmarks: Arbiter (arb), Ibex Compressed Decoder
(ibex_dec), Ibex Controller (ibex_con), Ibex Id-Stage
(ibex_id), Ibex Multdiv Slow (ibex_mul)

| | | # Unique | # Unique |
|---|---|---|---|
| | | Propositions | Propositions |
| Benchmark | # Assertions | in Antecedent | in Consequent |
| arb | 23 | 12 | 8 |
| ibex_dec | 1499 | 191 | 79 |
| ibex_con | 6602 | 1090 | 97 |
| ibex_id | 6447 | 1972 | 817 |
| ibex_mul | 2648 | 855 | 200 |

### 2. Assertion Clustering 254

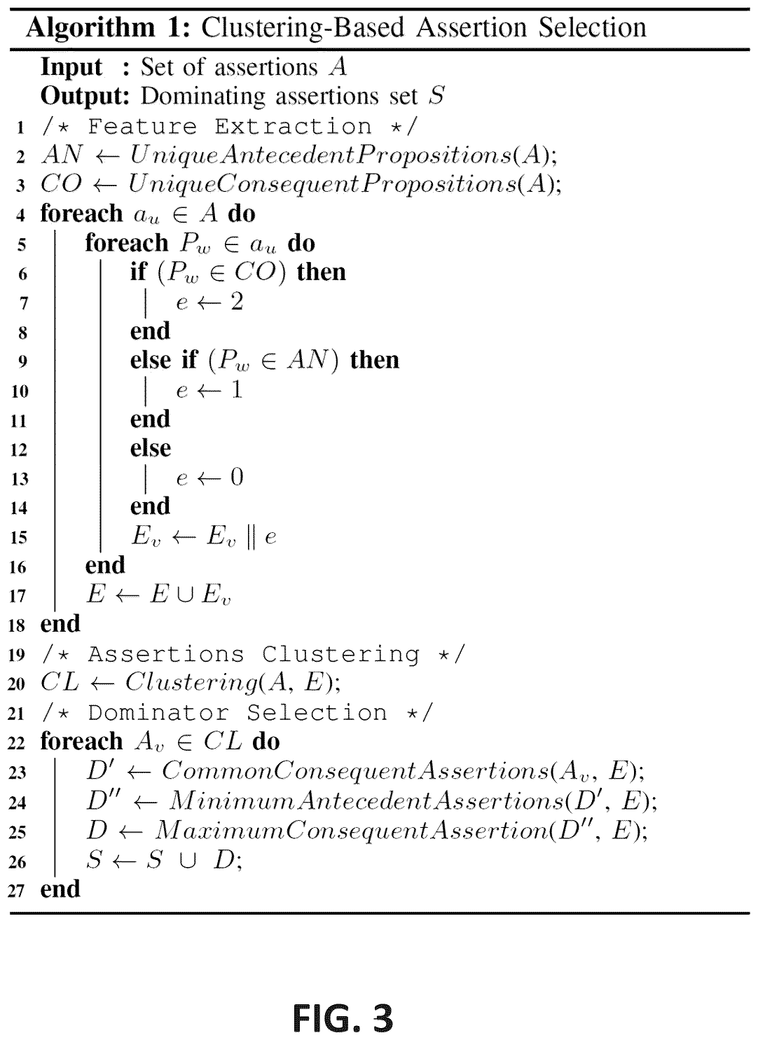

Clustering is an unsupervised learning technique that groups similar data points based on features. There are several clustering algorithms, such as K-means clustering, hierarchical clustering, density-based clustering, etc. BIRCH (Balanced Iterative Reducing and Clustering using Hierarchies) is a hierarchical clustering algorithm designed for large-scale datasets. BIRCH clustering can be used because it is more flexible in capturing clusters with varying shapes and densities and its hierarchical structure allows for a better representation of complex clusters, including those with varying densities or irregular shapes. In the present assertion selection method, input features for the clustering algorithm fully depend on the set of input assertions (A). BIRCH comprises a noise-handling mechanism called the “noise points” in its Clustering Feature tree (CF-tree). These points help capture and isolate noisy or outlier data, preventing them from significantly affecting the clustering process. Line 20 of Algorithm 1 (FIG. 3) depicts the clustering function of example frameworks herein (e.g., 250), which takes A, and E as inputs. The output of this function is the set of assertion clusters (CL).

### 3. Dominator Selection 256

Line 22-27 of Algorithm 1 (FIG. 3) is used to select the dominating assertion from the assertion clusters (CL). The algorithm finds the dominating assertion in each cluster by removing assertions that do not have common propositions in the consequent with the other assertions. Since examples of the present clustering method depend on the consequent proposition, line 23 of Algorithm 1 (FIG. 3) (CommonConisequentAssertions) removes assertions that do not have a common consequent proposition from the cluster and returns filtered clusters. Line 24 of Algorithm 1 (FIG. 3) (MinimumAntecedentAssertions) returns the set of assertions with the least number of propositions in the antecedent by using the filtered cluster. As discussed herein, a smaller number of propositions in the antecedent is better because it has relatively high non-vacuous failing states coverage. Line 25 of Algorithm 1 (FIG. 3) (MaximumConsequentAssertiont) finds the most suitable assertion from the remaining assertions in the cluster. If there is more than one suitable assertion, the function randomly selects an assertion from suitable assertions. The final set of selected assertions consists of one profitable assertion from each cluster.

### E. Dynamic Refinement of Hardware Checkers

The assertions selected as discussed herein are considered as inputs for dynamic refinement. FIG. 2B depicts an example dynamic refinement framework 200, in accordance with embodiments of the present disclosure. The dynamic refinement framework 200 includes cost prediction 202 and optimization 204. Cost prediction 202 includes learning how to predict cost (e.g., using a cost prediction model 206) for a given set of hardware checkers 208. Optimization 204 uses the trained model 206 to select (e.g., using optimized subset selection 210) the optimal set of hardware checkers 212 that satisfies the constraints 214 while minimizing the cost of adding the hardware checkers.

### 1. Cost Prediction 202

Cost prediction 202 includes estimating the functions F, PW and AR that appear in the optimization problem. Typically, the function F is a simple cost model depending on the functions P(S) (power) and A(S) (area) when implementing assertions in the set S. While the two problems (power and area) capture different aspects of circuit design, the estimation problem is essentially the same. The estimation problem is solved herein by modeling the problem as a regression problem with sets as inputs: Given samples S1, . . . , Sg and power consumption estimates p1=PW(S1), . . . , pg=PW(Sg) find a good approximation of the function PW(S). The same solution can be used for AR as well.

Most regression models only accommodate continuous inputs. Essentially, the regression models find non-linear mapping from R^{k}→R. To finish the translation of the cost estimation problem into a regression problem, the set input S is transformed into a continuous input by introducing an input i for the regression problem for each checker Ci. Next, the input value is set at 0.0 if Ci∉S and at 1.0 if Ci∈S. Thus, each set S is always mapped into a vector of size N that contains only 0.0 or 1.0 entries.

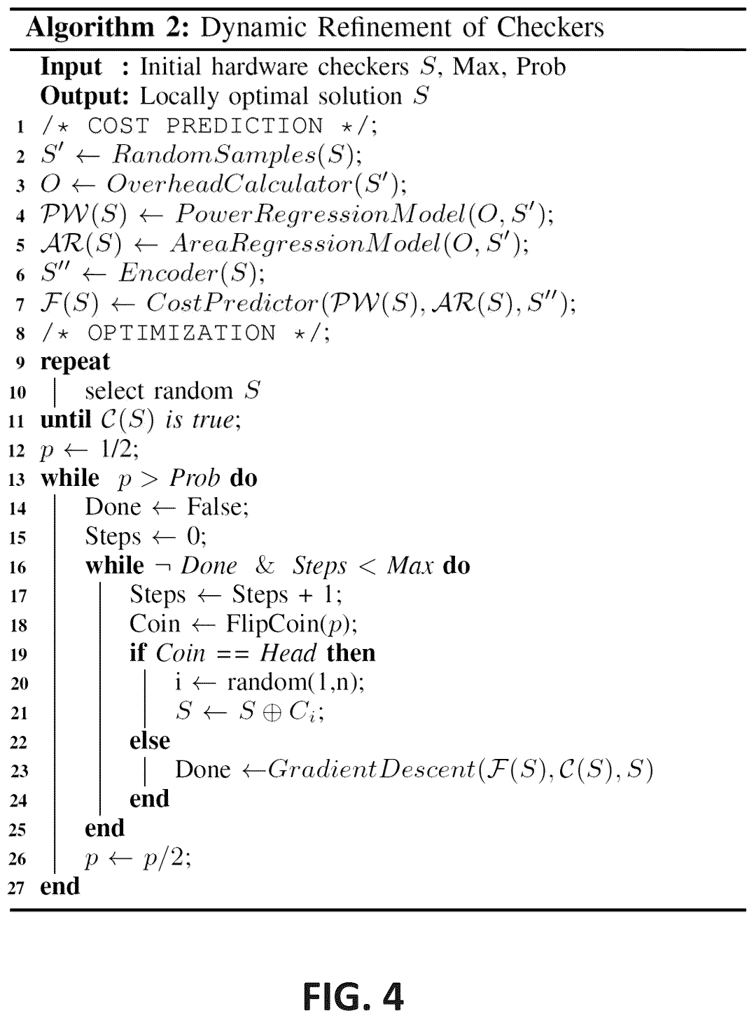

As shown in FIG. 2 (and in line 2 of Algorithm 2 (FIG. 4)), random sampling 216 is conducted on hardware checkers (S) 208 to get different sample subsets (S′) 218. Line 3 of Algorithm 2 (FIG. 4) uses these sample subsets 218 and synthesizes and simulates 220 them to aid in determining the overhead cost (O) 222 with respect to power and area. The overhead costs 222 are used to train a regression model 224 in lines 4-5 of Algorithm 2 (FIG. 4). Once learning models PW(S) and AR(S) (cost prediction model 206) are built, they can be used to predict F(S) by encoding the input S using the same 0.0, 0.1 mapping and using the predictor for the estimate. That is, the cost prediction model or models 206 can receive input and provide predictions as output.

### 2. Optimization 204

When non-linear optimization problem is relatively simple (e.g., it has a small number of local minimums), gradient descent methods perform fairly well. The optimization problem herein is likely to be complicated due to the interaction between the hardware checkers. In such situations, simulated annealing methods are preferred. The basic idea is to modify the gradient descent strategy by adding random feasible steps that allow local minimums to be escaped. The random steps are allowed more often in the beginning but less and less often as the computation progresses so the solution finds a better local minimum. As a result, embodiments herein utilize gradient descent with simulated annealing to solve the non-linear optimization problem.

Lines 9-27 of the Algorithm 2 (FIG. 4) presents a gradient descent search of the subset space with simulated annealing. Inputs of the algorithm are F(S) and C(S). Function F(S) is retrieved using the cost prediction model described in Section V-A. Function C(S) represents a Boolean function which combines all the constraints and indicates whether the constraints are satisfied for S or not. The results of this function will be a locally optimal solution S, which satisfy C(S). The algorithm begins at a random initial feasible subset (lines 9-11 of Algorithm 2 (FIG. 4)). First, the probability of the random step is given value 0.5 (line 12 of Algorithm 2 (FIG. 4)). Then, this probability is halved through the annealing loop (lines 13-27 of Algorithm 2 (FIG. 4)). The loop is conducted for ‘Max’ steps by checking whether the probability is greater than ‘Prob’. In each iteration, ‘FlipCoin’ is conducted to determine whether to move to the best feasible neighboring subset (lines 22-24 of Algorithm 2 (FIG. 4)) or to move to a random feasible neighboring subset (lines 19-21 of Algorithm 2 (FIG. 4)). A neighboring subset of S is one which has only one hardware checker added or removed relative to S. A subset is feasible when it satisfies the applied constraints. Function ‘FlipCoin’ will allow more random steps in the beginning (e.g., when p is large) but less random steps when p is smaller.

For the best feasible solution, the gradient descent function GradientDescent is used (line 23 of Algorithm 2 (FIG. 4)). The probability of a random move decreases by a factor of 0.5 every ‘Max’ steps (line 26 of Algorithm 2 (FIG. 4)). The algorithm stops when it attempts to move to the best neighboring subset, and no feasible neighbor is superior to the current solution.

There are several aspects that can change the parameters of the cost-based optimization problem. One is the value of including an assertion can shift significantly throughout the lifecycle. Assertions that seem marginal now can become very important due to discoveries of new functional exploits. Similarly, assertions that seem important now, can prove to have only marginal benefits in the future. Either the number of samples, the quality of the synthesis estimation or the learning methods can improve throughout the lifecycle. Another aspect is that if more computation can be afforded, it can result in better quality solutions for the optimization problem.

Based on the present formulation and solution for the cost-based optimization problem, a number of shortcuts can be taken to improve the running time of the solver. Specifically, the current best solution can be used as the starting point for the modified future optimization problem. It is likely that the problem will not shift significantly. The current solution should be in the neighborhood of the new optimal solution.

### IV. EXPERIMENTS

### A. Experimental Setup

For the experimental evaluation, benchmarks selected are shown in Table IV. The first column of the table shows the benchmarks. The second and third columns show the number of assertions mined using HARM and their fault coverage, respectively. Similarly, the fourth and fifth columns represent the number of assertions mined using Goldmine and their fault coverage, respectively. The sixth column presents the total number of assertions used for the clustering method. The seventh column shows the total number of inserted faults. The eighth and ninth columns show the number of code lines in the design and the total number of primary inputs/outputs respectively. The tenth column presents the number of assertions selected as hardware checkers for synthesis. The last column shows the number of samples used for the cost prediction model.

In the experiment setup, assertions are generated using HARM and Goldmine, and total assertions of HARM and Goldmine are used for the clustering method. All the assertions generated using HARM and Goldmine belong to the linear temporal logic assertion, and the maximum total delay in the assertion has been set to three cycles. The maximum number of propositions in the antecedent has been set to six, and all variables in the assertions are only Boolean type. A set of faults are inserted, which consist of (1) “bit flip”, where a bit of a selected variable is flipped and (2) “functional fault”, where the Boolean operation of a selected Boolean expression is changed with another Boolean operation. All the fault-inserted benchmarks are simulated for 1000 clock cycles to generate the trace files. These trace files are used to identify faults that are covered by each assertion, and that information is used to calculate fault coverage for different types of assertion sets. The number of faults that are covered by the selected set of assertions is counted. Fault coverage is calculated by expressing the number of covered faults as a percentage of the total number of inserted faults. Assertion generation as well as assertion selection was performed prior to fault injection. In other words, the clustering method did not have any knowledge of inserted faults.

The clustering-based assertion selection was carried out using a 2.9 GHz 8-core AMD Ryzen 7 4800HS processor equipped with 16 GB of RAM. The dynamic refinement of hardware checkers was evaluated using the Zynq-7000 SoC based evaluation platform. The original design as well as the design with embedded assertions were synthesized to the FPGA in the SoC. Xilinx Vivado Design Suite 2021 was utilized to perform synthesis, optimization, and place and route for the designs. The same software was then used to perform timing-accurate simulation of the FPGA mapped designs, emulating both the functional and timing constraints of the FPGA architecture.

TABLE IV
Benchmarks details

| | HARM | | Goldmine | | Total | | | | | |
|---|---|---|---|---|---|---|---|---|---|---|
| Benchmark | #Assertions | Coverage | #Assertions | Coverage | Assertions | #Faults | #Lines | I/O | #Checkers | #Samples |
| arb | 17 | 100.00% | 6 | 58.33% | 23 | 12 | 28 | 6 | 6 | 50 |
| ibex_dec | 933 | 100.00% | 566 | 100.00% | 1499 | 848 | 97 | 4 | 20 | 1000 |
| ibex_con | 5480 | 30.99% | 1122 | 24.41% | 6602 | 926 | 459 | 57 | 10 | 300 |
| ibex_id | 5374 | 83.23% | 1073 | 36.43% | 6447 | 1002 | 484 | 82 | 20 | 1000 |
| ibex_mul | 2212 | 69.19% | 436 | 3.13% | 2648 | 1980 | 230 | 15 | 10 | 300 |

### B. Assertion Selection Results

Table VI reports the fault coverage results for the five benchmarks outlined in Table IV. The first column shows the benchmark name. The second column represents the number of selected assertions, which is the number of selected ranked assertions from the top in HARM and Goldmine, and the number of clusters in the clustering method. For example, if the number of selected assertions is 73, all of the following conditions are true: (i) the top 73 assertions have been selected from the HARM ranked assertions, (ii) the top 73 assertions from the Goldmine ranked assertions have been selected, and (iii) 73 clusters in the clustering method have been considered to select 73 assertions. The last three columns show the fault coverage of HARM, Goldmine, and the clustering method, respectively. The coverage is indicated as a percentage of the number of inserted faults.

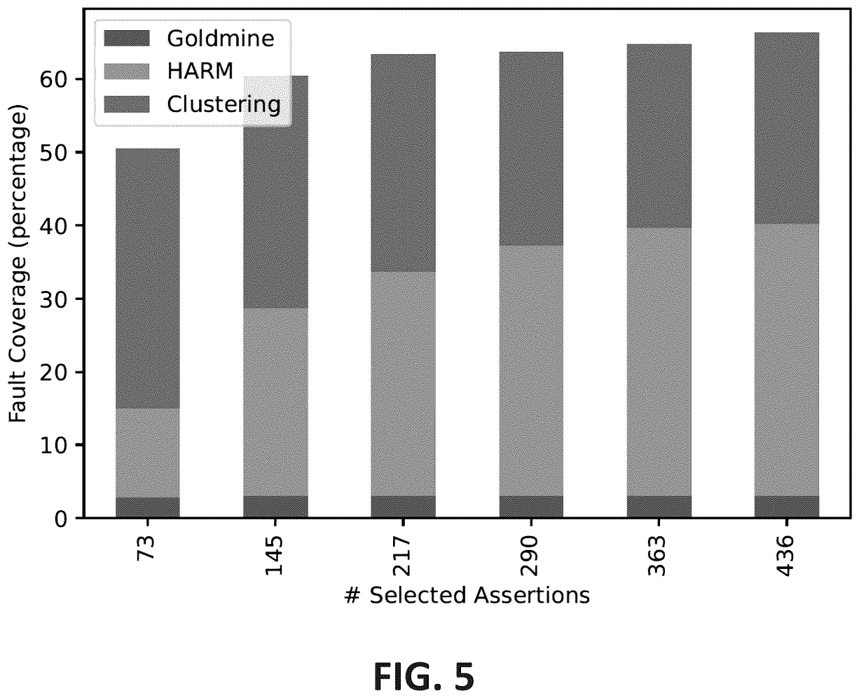

The number of mined assertions using Goldmine is less than HARM. Therefore, the number of Goldmine assertions is used as the upper bound for the number of selected assertions. Then that number is divided into six subsets to analyze the fault coverage. It shows that the clustering-based assertion selection consistently provides higher fault coverage than HARM and Goldmine. For example, in the ibex mul benchmark, the maximum number of selected assertions is 436 (number of assertions generated using Goldmine). That number is set as the upper bound and divide the number of assertions space into six almost equal sets. Therefore, each row increment represents a 16.67% increment in the number of assertions. The fault coverage is calculated for selected assertions, and it has been represented as a percentage of the total number of inserted faults. The present clustering method consistently outperforms both HARM (78% on average) and Goldmine (6 times on average) in terms of fault coverage. FIG. 5 provides an alternate visualization of the fault coverage results of Table VI for the ibex mul benchmark.

TABLE V
Fault coverage comparison using assertions generated by HARM

| | HARM | | Clustering | | | |
|---|---|---|---|---|---|---|
| | | Fault | | Fault | % Reduction | Loss in |
| Benchmark | # Assertions | Coverage | # Assertions | Coverage | in Assertions | Fault Coverage |
| arb | 2 | 33.33% | 1 | 33.33% | 50.00% | 0.00% |
| ibex_dec | 189 | 100.00% | 94 | 100.00% | 50.26% | 0.00% |
| ibex_con | 374 | 16.74% | 187 | 14.90% | 50.00% | 10.97% |
| ibex_id | 358 | 25.15% | 179 | 25.15% | 50.00% | 0.00% |
| ibex_mul | 145 | 28.74% | 73 | 28.28% | 49.66% | 1.58% |

Table V shows fault coverage results for assertion minimization of the top-ranked HARM assertions. An objective is to determine if the number of top ranked HARM assertions can be reduced with negligible impact on fault coverage. The same five benchmarks as shown in the first column are used. The second column shows the number of selected HARM assertions, and the third column shows the corresponding fault coverage. The fourth and fifth columns show the number of assertions after the minimization using the present clustering method and corresponding fault coverage, respectively. The sixth column shows the reduction in the number of assertions as a percentage of the initial number of HARM assertions. The final column shows the loss in the fault coverage due to reduction in assertions. It is observed that the present clustering method can significantly (50% on average) reduce the top-ranked HARM assertions with minor loss (2.51% on average) in fault coverage.

TABLE VI
Comparison of assertion selection results

| | # Selected | Fault Coverage | | |
|---|---|---|---|---|
| Benchmark | Assertions | HARM | Godmine | Clustering |
| arb2 | 1 | 33.33% | 8.33% | 41.67% |
| | 2 | 33.33% | 33.33% | 50.00% |
| | 3 | 33.33% | 58.33% | 100.00% |
| | 4 | 33.33% | 58.33% | 100.00% |
| | 5 | 100.00% | 58.33% | 100.00% |
| | 6 | 100.00% | 58.33% | 100.00% |
| ibex_dec | 94 | 100.00% | 5.66% | 100.00% |
| | 189 | 100.00% | 8.84% | 100.00% |
| | 283 | 100.00% | 14.15% | 100.00% |
| | 377 | 100.00% | 15.68% | 100.00% |
| | 472 | 100.00% | 16.98% | 100.00% |
| | 566 | 100.00% | 100.00% | 100.00% |
| ibex_con | 187 | 14.79% | 9.61% | 30.78% |
| | 374 | 16.74% | 18.79% | 35.31% |
| | 561 | 17.17% | 22.57% | 36.39% |
| | 748 | 17.49% | 23.87% | 36.50% |
| | 935 | 19.01% | 23.87% | 36.83% |
| | 1122 | 19.01% | 24.41% | 36.83% |
| ibex_id | 179 | 14.77% | 8.58% | 31.14% |
| | 358 | 25.15% | 18.06% | 57.98% |
| | 536 | 32.53% | 22.95% | 70.76% |
| | 715 | 39.12% | 28.64% | 75.85% |
| | 894 | 41.52% | 32.73% | 79.94% |
| | 1073 | 52.79% | 36.43% | 80.24% |
| ibex_mul | 73 | 15.00% | 2.83% | 50.45% |
| | 145 | 28.74% | 3.13% | 60.35% |
| | 217 | 33.74% | 3.13% | 63.38% |
| | 290 | 37.27% | 3.13% | 63.69% |
| | 363 | 39.70% | 3.13% | 64.70% |
| | 436 | 40.25% | 3.13% | 66.26% |

When it comes to post-silicon validation and debug, the number of hardware checkers is determined by design constraints such as area and power. For example, only 6 assertions were selected for the smallest (arb) benchmark, while 20 assertions were allowed for a larger (ibex . . . dec) benchmark. Table VII shows the reduced number of assertions for different benchmarks. The present clustering method outperforms HARM and Goldmine generated assertions. These reduced set of assertions as the hardware checkers were used to evaluate cost prediction and dynamic refinement herein.

TABLE VII
Fault coverage comparison for final set of hardware
checkers considering design constraints

| | # Selected | Fault Coverage | | |
|---|---|---|---|---|
| Benchmark | Assertions | HARM | Godmine | Clustering |
| arb2 | 6 | 100.00% | 58.33% | 100.00% |
| ibex_dec | 20 | 100.00% | 2.24% | 100.00% |
| ibex_con | 10 | 0.86% | 3.46% | 6.37% |
| ibex_id | 20 | 0.00% | 2.10% | 6.29% |
| ibex_mul | 10 | 3.38% | 2.78% | 16.57% |

### C. Cost Prediction Results

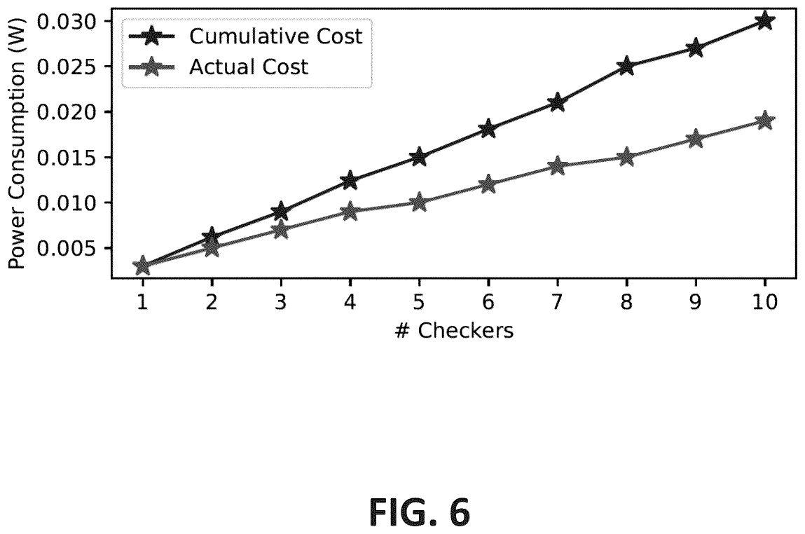

FIG. 6 depicts example power consumption results, in accordance with embodiments of the present disclosure. To emphasize that the cost function F(S) is not simply linear, an experiment was conducted where the power consumption of individual checkers and the power consumption of number of the checkers were calculated together. FIG. 6 presents the power consumption (in watts) for different number of checkers for ibex con design. FIG. 6 shows the cumulative cost (addition of individual checkers) and the actual power consumption for the same number of checkers. The cumulative cost of the 10 individual checkers is 0.030 watts. However, when the 10 checkers are together, the power consumption is 0.019 watts. This shows that the cost function F(S) is non-linear. Therefore, it is important to use cost prediction techniques to predict the cost rather than synthesizing all possible combinations of checkers.

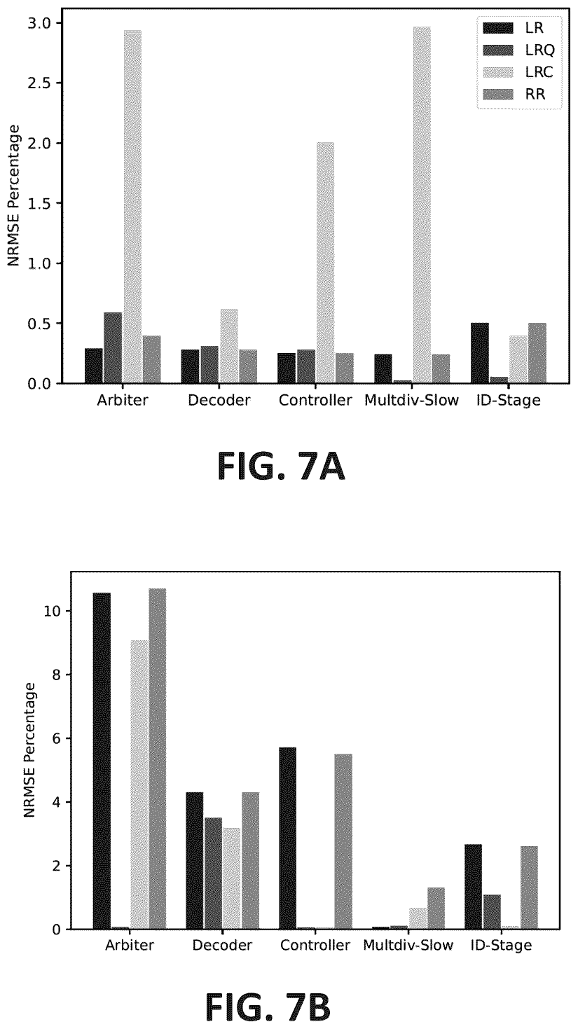

The size of Lookup Tables (LUT) and power overhead are selected as parameters for the cost prediction framework. To enable approximate prediction of the cost function, the efficacy of four models was evaluated: (1) linear regression (LR), (2) linear regression with quadratic interaction (LRQ), (3) linear regression with cubic interaction terms (LRC), and ridge regression (RR). The training data was generated by collecting LUT and power data from a random sample of subsets from the set of all possible subsets for each design. Each assertion subset in the sample was then synthesized, optimized, placed, and routed. Hardware and power utilization data for each subset in the sample was then dumped, which would serve as the training data. For example, in case of ibex_con, a sample of 300 subsets was collected, covering 29.29% of all possible subsets. Similarly, in case of ibex_dec, 1000 subsets were collected, covering 0.95% of all possible subsets. This data set was then randomly partitioned into a train and test set, using an 80-20 train-test split. First, the performance of the models on unseen data was estimated by training and evaluating the models on the train set using 10-fold cross validation, with normalized root mean squared error (NRMSE) as the performance metric. The performance evaluation for all four models for each benchmark with respect to power and LUT consumption is shown in FIGS. 7A and 7B. For all the designs, the four models achieved less than 3% error predicting the power consumption and less than 5% error predicting LUT.

The model with the best performance on the test set for each metric and design pair (FIGS. 7A and 7B) was then utilized during the subset selection algorithm in dynamic refinement to predict the LUT and power overhead for potential selected hardware checker subsets. By estimating whether a checker subset satisfied the applied constraints, the subset selection algorithm produced results without the processing bottleneck of HDL synthesis for each subset and its neighbors.

### D. Dynamic Refinement Results

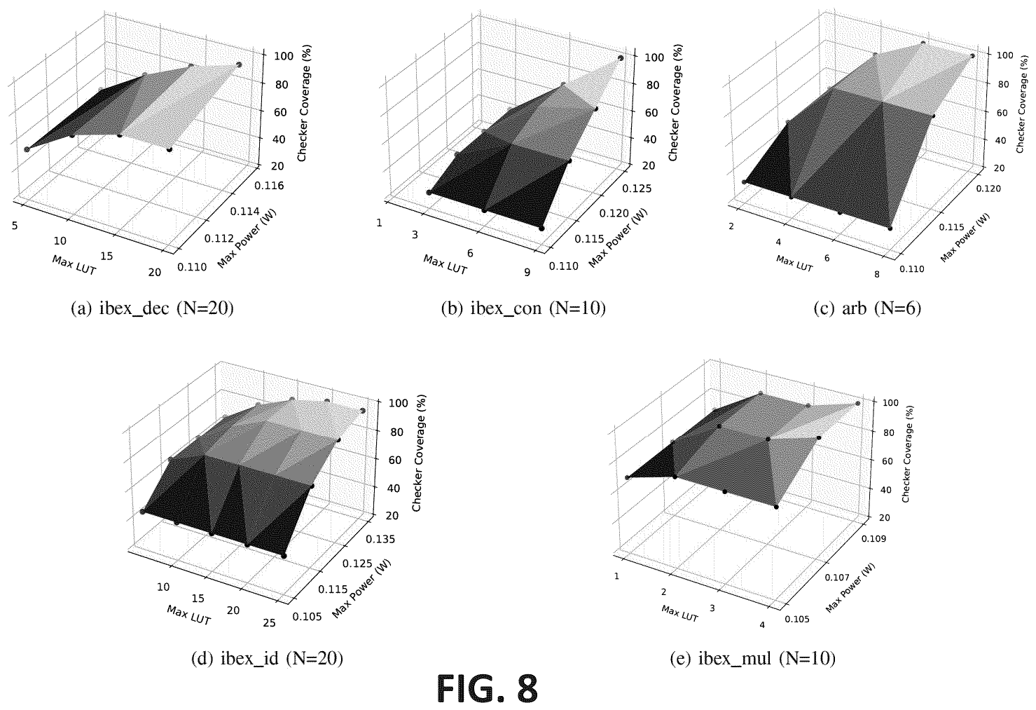

FIG. 8 depicts example dynamic refinement of hardware checkers with different constraints, in accordance with embodiments of the present disclosure. The subset selection algorithm was run for all designs with a variety of parameters, including LUT constraints, power constraints, and number of iterations (by changing the ‘prob’ value). FIG. 8 shows the dynamic refinement of hardware checkers for each benchmark with different constraints. For each benchmark, the number of checkers selected as optimal subset is shown in checker coverage as a percentage of all the number of checkers in the initial set (N). The dynamic refinement is performed with increasing iterations from 5 to 100 for all the constraints pairs. FIG. 8 shows the optimal selection of hardware checkers for each constraints pair chosen from the results from different iterations.

When the design constraints are loosened, the achievable assertion coverage increases. For all the designs, the highest coverage values are achieved with maximum LUT of 45 and power of 0.155 watts. As the constraints are tightened, the coverage value tends to decrease as the algorithm must sacrifice coverage for feasibility. The loss in coverage for each decreasing step in one constraint value is not linear. Instead, the coverage begins to decrease more rapidly as the constraints decrease to values significantly below the mean value of the metrics for random subsets. This may be indicative of the fact that the propensity of the algorithm to find locally optimal, but globally sub-optimal solutions increases as the constraints are tightened due to the local search being constrained by a high amount of infeasible neighbors. It also may arise from the underlying distribution of subset overhead values being non-uniform. In other words, the fraction of subsets satisfying the tight constraints is lower than expected from a uniform distribution.

The results of running the dynamic refinement algorithm for ibex con benchmark with increasing iterations (5 to 100) are shown in Table VIII. The first two columns provide design constraints in terms of upper limit on the number of LUTs available and power consumption (in Watts). Each row represents a different configuration in terms of constraints. The number of checkers selected for synthesis is shown in brackets. The solution subset is presented as a bit-string, where the i-th bit being 1 implies that the i-th checker was included in the solution. For each solution, the power and LUT values are also shown in the table. Note that significant increase in the number of iterations does not dramatically improve the achieved coverage. For example, the algorithm achieved a coverage of 8 (80.00%) with optimal solution even from 10 iterations for LUT=9 and Power=0.120 W on the ibex con design. However, for some constraints increasing the number of iterations helped to achieve the optimal solution (LUT=3 and Power=0.110).

Overall, the subset selection algorithm allowed for consistent performance under constraints in achievable ranges and did not require significant iterations to find satisfactory solutions. The algorithm's speed and relative simplicity are positive indicators of the potential efficacy of this method in the dynamic refinement of on-chip security assertions. The present algorithm represents a highly extensible foundation which can be augmented with additional constraints, such as novel cost functions, and time dependent behaviors, all of which potentially appear in industrial applications.

TABLE VIII
Dynamic refinement results for ibex_con with different iterations

| LUT | Power(W) | Iterations = 5 | Iterations = 10 | Iterations = 20 | Iterations = 40 | Iterations = 100 |
|---|---|---|---|---|---|---|
| 3 | 0.110 | “0001000011” (3) | “0010100010” (3) | “0001000011” (3) | “0000100011” (3) | “0000100011” (3) |
| | | P = 0.10984, LUT = 2.99 | P = 0.10987, LUT = 2.99 | P = 0.10984, LUT = 2.99 | P = 0.10982, LUT = 2.00 | P = 0.10982, LUT = 2.00 |
| 6 | 0.115 | “0011011011” (6) | “0011011011” (6) | “0110101011” (6) | “0010111011” (6) | “0010111011” (6) |
| | | P = 0.11493, LUT = 6.00 | P = 0.11493, LUT = 6.00 | P = 0.11493, LUT = 4.99 | P = 0.11491, LUT = 5.00 | P = 0.11491, LUT = 5.00 |
| 9 | 0.120 | “0110111111” (8) | “0111111011” (8) | “0111111011” (8) | “0111111011” (8) | “0111111011” (8) |
| | | P = 0.11836, LUT = 7.00 | P = 0.11836, LUT = 6.99 | P = 0.11836, LUT = 6.99 | P = 0.11836, LUT = 6.99 | P = 0.11836, LUT = 6.99 |

### V. CONCLUSION

Post-silicon validation relies on observability infrastructure such as trace buffers. Hardware checkers can improve the observability for debugging functional as well as non-functional (e.g., security) violations. Due to hardware overhead considerations, it is not feasible to map all pre-silicon assertions as post-silicon hardware checkers. While there are promising approaches for selecting a small set of profitable assertions for synthesis, they are inefficient under a vast number of pre-silicon assertions and changing workloads and input variations. Embodiments herein present efficient methods for feature selection, assertion clustering, and dominator selection to enable clustering-based assertion minimization while maintaining considerable fault coverage. The selected pre-silicon assertions are utilized as inputs for post-silicon dynamic refinement. The dynamic refinement problem is defined herein as a cost-based non-linear optimization problem. Regression-based learning is used to perform cost prediction for hardware checkers. The non-linear optimization problem is solved using gradient descent with simulated annealing. The experimental evaluation demonstrated the effectiveness of assertion minimization as well as dynamic refinement. The present clustering method provided significantly higher fault coverage compared to top-ranked HARM (78% on average) and Goldmine (6 times on average) assertions. Similarly, cost prediction herein is reasonably accurate (less than 3% and 5% error in predicting power and area, respectively). Finally, the present dynamic refinement is able to find the optimal solution quickly (less than 10 iterations).

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

1. A method for dynamically refining hardware assertion checkers of an integrated circuit (IC) design, the method comprising:
receiving a plurality of hardware assertion checkers;
receiving one or more design constraints;
based at least in part on applying a cost prediction model to the plurality of hardware assertion checkers, generating a predicted overhead cost associated with the plurality of hardware assertion checkers;
based at least in part on the predicted overhead cost and the one or more design constraints, selecting an optimal hardware assertion checker set; and
synthesizing the optimal hardware assertion checker set.

2. The method of claim 1, wherein the cost prediction model is generated by:
selecting hardware assertion checker subsets from a plurality of hardware assertion checkers;
determining a plurality of overhead costs by, for each hardware assertion checker subset, determining an overhead cost associated with the hardware assertion checker subset by synthesizing and simulating the hardware assertion checker subset; and
training a regression model using the plurality of overhead costs.

3. The method of claim 2, wherein the plurality of overhead costs comprises one or more of power, area, thermal, temperature, accuracy, functional coverage, security, vulnerability coverage, or debuggability.

4. The method of claim 1, wherein the optimal hardware assertion checker set is synthesized in reconfigurable hardware or a device with reconfigurability.

5. The method of claim 1, wherein selecting the optimal hardware assertion checker set is further based at least in part on gradient descent, gradient descent with simulated annealing, or other minimization technique.

6. The method of claim 1, wherein the optimal hardware assertion checker set comprises those hardware assertion checkers of the plurality of hardware assertion checkers satisfying the one or more design constraints while minimizing overhead cost.

7. The method of claim 1, wherein the cost prediction model comprises a machine learning model.

8. The method of claim 1, wherein the hardware assertion checkers are associated with functional assertions.

9. The method of claim 1, wherein the hardware assertion checkers comprise one or more of functional checkers, security checkers, safety checkers, or reliability checkers.

10. A system comprising memory and one or more processors configured to:
receive a plurality of hardware assertion checkers;
receive one or more design constraints;
based at least in part on applying a cost prediction model to the plurality of hardware assertion checkers, generate a predicted overhead cost associated with the plurality of hardware assertion checkers;
based at least in part on the predicted overhead cost and the one or more design constraints, select an optimal hardware assertion checker set; and
synthesize the optimal hardware assertion checker set.

11. The system of claim 10, wherein the cost prediction model is generated by:
selecting hardware assertion checker subsets from a plurality of hardware assertion checkers;
determining a plurality of overhead costs by, for each hardware assertion checker subset, determining an overhead cost associated with the hardware assertion checker subset by synthesizing and simulating the hardware assertion checker subset; and
training a regression model using the plurality of overhead costs.

12. The system of claim 11, wherein the plurality of overhead costs comprises one or more of power, area, thermal, temperature, accuracy, functional coverage, security, vulnerability coverage, or debuggability.

13. The system of claim 10, wherein the optimal hardware assertion checker set is synthesized in reconfigurable hardware or a device with reconfigurability.

14. The system of claim 10, wherein selecting the optimal hardware assertion checker set is further based at least in part on gradient descent, gradient descent with simulated annealing, or other minimization technique.

15. The system of claim 10, wherein the optimal hardware assertion checker set comprises those hardware assertion checkers of the plurality of hardware assertion checkers satisfying the one or more design constraints while minimizing overhead cost.

16. The system of claim 10, wherein the cost prediction model comprises a machine learning model.

17. The system of claim 10, wherein the hardware assertion checkers are associated with functional assertions.

18. The system of claim 10, wherein the hardware assertion checkers comprise one or more of functional checkers, security checkers, safety checkers, or reliability checkers.

19. A non-transitory computer readable storage medium comprising instructions that, when executed by one or more processors, cause the one or more processors to:
receive a plurality of hardware assertion checkers;
receive one or more design constraints;
based at least in part on applying a cost prediction model to the plurality of hardware assertion checkers, generate a predicted overhead cost associated with the plurality of hardware assertion checkers;
based at least in part on the predicted overhead cost and the one or more design constraints, select an optimal hardware assertion checker set; and
synthesize the optimal hardware assertion checker set.

20. The non-transitory computer readable storage medium of claim 19, wherein the cost prediction model is generated by:
selecting hardware assertion checker subsets from a plurality of hardware assertion checkers;
determining a plurality of overhead costs by, for each hardware assertion checker subset, determining an overhead cost associated with the hardware assertion checker subset by synthesizing and simulating the hardware assertion checker subset; and
training a regression model using the plurality of overhead costs.
